(19) United States
(12) Patent Application Publication
(10) Pub. No.: US 2018/0257980 A1
(43) Pub. Date: Sep. 13, 2018

(54) COATED ARTICLE HAVING LOW-E COATING WITH IR REFLECTING LAYER(S) AND DOPED TITANIUM OXIDE BI-LAYER FILM DIELECTRIC AND METHOD OF MAKING SAME

(71) Applicant: Guardian Industries Corp., Auburn Hills, MI (US)

(72) Inventors: Gaurav SARAF, San Jose, CA (US); Guowen DING, San Jose, CA (US); Minh LE, San Jose, CA (US); Daniel SCHWEIGERT, San Jose, CA (US); Guizhen ZHANG, San Jose, CA (US); Daniel LEE, San Jose, CA (US); Scott JEWHURST, San Jose, CA (US); Cesar CLAVERO, San Jose, CA (US); Marcus FRANK, Gelhausen (DE); Nestor P. MURPHY, West Bloomfield, MI (US)

(21) Appl. No.: 15/451,448

(22) Filed: Mar. 7, 2017

(51) Int. Cl. C03C 17/36; C23C 14/08; C23C 14/18; C23C 14/34; G02B 5/08; G02B 5/28

(52) U.S. Cl. CPC C03C 17/3618; C03C 17/3642; C03C 17/3644; C03C 17/366; C23C 14/083; C03C 2218/154; C23C 14/34; G02B 5/0858; G02B 5/282; C03C 2217/212; C23C 14/185

(57) ABSTRACT

A coated article includes a low emissivity (low-E) coating having at least one infrared (IR) reflecting layer of a material such as silver, gold, or the like, and at least one high refractive index bi-layer film of or including doped titanium oxide (e.g., TiO₂ doped with at least one additional element). The titanium oxide based bi-layer film may be of or include a first titanium oxide based layer doped with a first element, and an adjacent second titanium oxide based layer doped with a different second element.

Example embodiments of this invention relate to a coated article including a low emissivity (low-E) coating having at least one infrared (IR) reflecting layer of a material such as silver, gold, or the like, and at least one high refractive index bi-layer film of or including doped titanium oxide (e.g., TiO₂ doped with additional elements). The titanium oxide based bi-layer film may be of or include a first titanium oxide based layer doped with a first element, and an adjacent second titanium oxide based layer doped with a different second element. The doped titanium oxide bi-layer film may be deposited in a manner so as to be amorphous or substantially amorphous (as opposed to crystalline) in the low-E coating, so as to better withstand optional heat treatment (HT) such as thermal tempering. The high index bi-layer film may be a transparent dielectric high index layer in preferred embodiments, which may be provided for antireflection purposes and/or color adjustment purposes, in addition to having thermal stability. In certain example embodiments, the low-E coating may be used in applications such as monolithic or insulating glass (IG) window unit, vehicle windows, of the like.

### BACKGROUND AND SUMMARY OF EXAMPLE EMBODIMENTS OF THE INVENTION

Coated articles are known in the art for use in window applications such as insulating glass (IG) window units, vehicle windows, monolithic windows, and/or the like.

Conventional low-E coatings are disclosed, for example and without limitation, in U.S. Pat. Nos. 6,576,349, 9,212,417, 9,297,197, 7,390,572, 7,153,579, and 9,403,345, the disclosures of which are hereby incorporated herein by reference.

Certain low-E coatings utilize at least one transparent dielectric layer of titanium oxide (e.g., TiO₂), which has a high refractive index (n), for antireflection and/or coloration purposes. See for example U.S. Pat. Nos. 9,212,417, 9,297,197, 7,390,572, 7,153,579, and 9,403,345. Although high refractive index dielectric materials such as TiO₂ are known and used in low-E coatings, these materials are not thermally stable and are typically not heat stable after a thermal tempering process of about 650 C for 8 minutes, due to film crystallization (or change in crystallinity) in as-deposited or post-tempering state, which may in turn induce thermal or lattice stress on adjacent layers in the film stack. Such stress can further cause change in physical or material properties of the stack and hence impact on the Ag layer, which results in deteriorated low E stack performance. In other words, conventional TiO₂ layers are typically sputter-deposited so as to realize a crystalline structure, which leads to damage to the stack upon HT as explained above.

Example embodiments of this invention solve these problems by providing a high index doped titanium oxide based bi-layer film, including two or more layers, for use in a low-E coating that both has a high refractive index (n) and is substantially stable upon heat treatment (HT).

“Heat treatment” (HT) and like terms such as “heat treating” and “heat treated”, such as thermal tempering, heat strengthening, and/or heat bending, as used herein means heat treating the glass substrate and coating thereon at temperature of at least 580 degrees C. for at least 5 minutes. An example heat treatment is heat treating at temperature of about 600-650 degrees C. for at least 8 minutes.

In example embodiments of this invention, a coated article includes a low emissivity (low-E) coating having at least one infrared (IR) reflecting layer of a material such as silver, gold, or the like, and at least one high refractive index bi-layer film of or including doped titanium oxide (e.g., TiO₂ doped with additional elements). The titanium oxide based bi-layer film includes two or more layers and may be of or include a first titanium oxide based layer doped with at least a first element, and an adjacent second titanium oxide based layer doped with at least a different second element. Examples dopants are Sn, Zr, Y, Ba, Nb, and ZnSn. The doped titanium oxide bi-layer film may be deposited in a manner so as to be amorphous or substantially amorphous (as opposed to crystalline) in the low-E coating, so as to better withstand optional heat treatment (HT) such as thermal tempering. The high index bi-layer film may be a transparent dielectric high index layer in preferred embodiments, which may be provided for antireflection purposes and/or color adjustment purposes, in addition to having thermal stability. In certain example embodiments, the low-E coating may be used in applications such as monolithic or insulating glass (IG) window units, vehicle windows, or the like.

In an example embodiment of this invention, there is provided a coated article including a coating supported by a glass substrate, the coating comprising: a first transparent dielectric film on the glass substrate; an infrared (IR) reflecting layer comprising silver on the glass substrate, located over at least the first transparent dielectric film; a second transparent dielectric film on the glass substrate, located over at least the IR reflecting layer; and wherein at least one of the first and second transparent dielectric films comprises a first layer comprising an oxide of titanium doped with a first metal element M1, and a second layer comprising an oxide of titanium doped with a second metal element M2 that is located over and directly contacting the first layer comprising the oxide of titanium doped with the first element M1, and wherein the first and second elements M1 and M2 are different.

### BRIEF DESCRIPTION OF THE DRAWINGS

This patent or application file contains at least one drawing executed in color. Copies of this patent or patent application publication with color drawing(s) will be provided by the Office upon request and payment of the necessary fee.

FIG. 1 is a cross sectional view of a coated article according to an example embodiment of this invention.

FIG. 2 is a percentage (%) versus wavelength (nm) graph plotting transmission (T) %, glass side reflection (G) %, and film side reflection (F) % of a Comparative Example (CE) layer stack including a high index 27 nm thick undoped TiO₂ layer versus wavelength (nm) in both as-coated (AC) and post-HT (HT) states.

FIG. 3 is a percentage (%) versus wavelength (nm) graph plotting transmission (T) %, glass side reflection (G) %, and film side reflection (F) % versus wavelength (nm) in both as-coated (AC) and post-HT (HT) states of a layer stack according to Example 1 where the undoped TiO₂ layer of FIG. 2 was replaced with a bi-layer film of TiZrOₓ (13.5 nm)/TiSnOₓ (13.5 nm).

FIG. 4 is a percentage (%) versus wavelength (nm) graph plotting transmission (T) %, glass side reflection (G) %, and film side reflection (F) % versus wavelength (nm) in both as-coated (AC) and post-HT (HT) states of a layer stack according to Example 2 where the undoped TiO₂ layer of FIG. 2 was replaced with a bi-layer film of TiSnOₓ (13.5 nm)/TiZrOₓ (13.5 nm).

FIG. 5 is a percentage (%) versus wavelength (nm) graph plotting transmission (T) %, glass side reflection (G) %, and film side reflection (F) % versus wavelength (nm) in both as-coated (AC) and post-HT (HT) states of a layer stack according to Example 3 where the undoped TiO₂ layer of FIG. 2 was replaced with a bi-layer film of TiZrOₓ (10 nm)/TiSnOₓ (17 nm).

FIG. 6 is a cross sectional view of a coated article according to another example embodiment of this invention.

### DETAILED DESCRIPTION OF EXAMPLE EMBODIMENTS OF THE INVENTION

Referring now to the drawings in which like reference numerals indicate like parts throughout the several views.

Coated articles herein may be used in applications such as monolithic windows, IG window units such as residential windows, patio doors, vehicle windows, and/or any other suitable application that includes single or multiple substrates such as glass substrates.

High refractive index material such as TiO₂ with low or no light absorption in the visible range is often used in low-E coatings in window applications. However, TiO₂ is typically not heat stable after a thermal tempering process such as involving HT at about 650 C for 8 minutes, due to film crystallization (or change in crystallinity) in as-deposited or post-tempering state, which may in turn induce thermal or lattice stress on adjacent layers in the film stack. Such a stress can further cause change in physical or material properties of the stack and hence impact on the IR reflecting Ag based layer, which results in deteriorated low E stack performance.

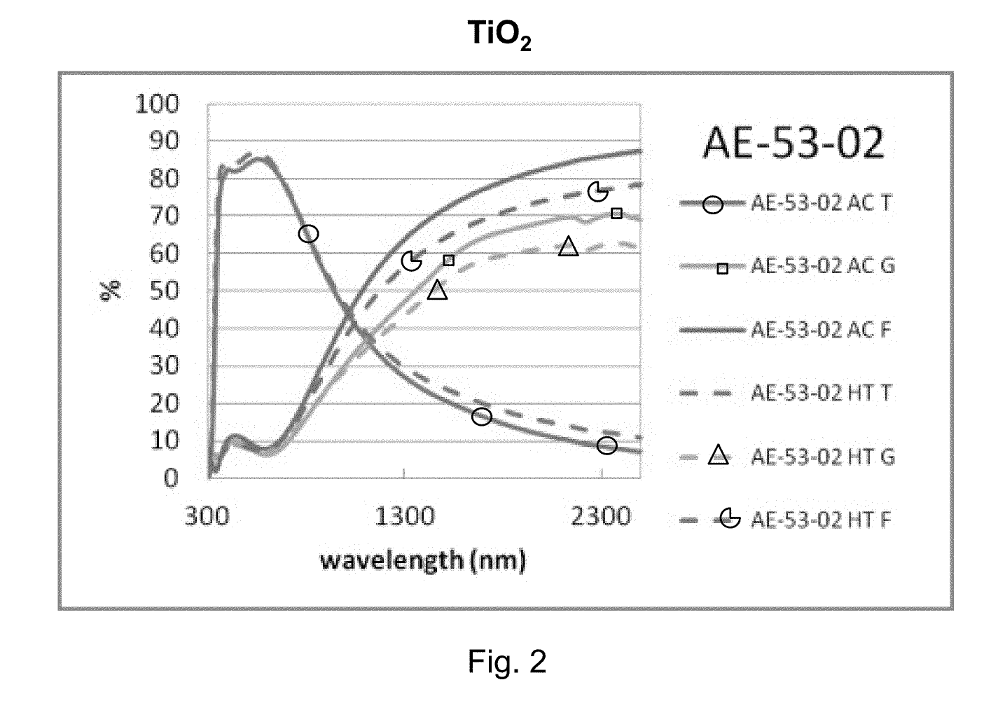

FIG. 2 illustrates that high index TiO₂ is not thermally stable, and thus is not heat treatable from a practical point of view. FIG. 2 is a percentage (%) versus wavelength (nm) graph plotting transmission (T) %, glass side reflection (G) %, and film side reflection (F) % of a layer stack including a high index titanium oxide layer versus wavelength (nm) in both as-coated (AC) and post-HT states. The stack was glass/TiO₂ (27 nm)/ZnO (4 nm)/Ag (11 nm)/NiTiNbOₓ (2.4 nm)/ZnSnO (10 nm)/ZnO (4 nm)/SiN (10 nm), where the ZnO layers were doped with Al in this Comparative Example (CE) stack. Thus, the “AC” curves are prior to HT, and the “HT” curves are after heat treatment at about 650 degrees C. for about eight minutes. In FIG. 2, at the right side where the curves are listed, the top three are as coated (AC) which means prior to the HT, and the bottom three are following the heat treatment and thus are labeled “HT.” FIG. 2 shows that the layer stack with the crystalline TiO₂ is not thermally stable and thus not practically heat treatable. In particular, the Comparative Example (CE) of FIG. 2 shows a significant shift in the IR range of the transmission and reflectance spectra, and increases in emissivity and haze were also found. In FIG. 2, in the wavelength area from about 1500 to 2400 nm, there was a shift due to HT from the “AC T” (transmission, as coated prior to HT) curve to the “HT T” (transmission, after HT) curve of about 6%; there was a shift due to HT from the “AC G” (glass side reflectance, as coated prior to HT) curve to the “HT G” (glass side reflectance, after HT) curve of about 12-14%; and there was a shift due to HT from the “AC F” (film side reflectance, as coated prior to HT) curve to the “HT F” (film side reflectance, after HT) curve of about 12-13%. Overall, taken together in combination, there is a significant shift in transmission and reflection spectra upon HT which indicates a lack of thermal stability for the Comparative Example (CE) shown in FIG. 2.

Example embodiments of this invention provide for a high index doped titanium oxide dielectric film, including two or more layers, designed to suppress crystallinity, irrespective of HT conditions such as thermal tempering. A high index doped titanium oxide dielectric film 2 for use in low-E coatings is provided that has a high refractive index (n) and is preferably amorphous or substantially amorphous as deposited and after HT, and thus substantially stable upon heat treatment (HT).

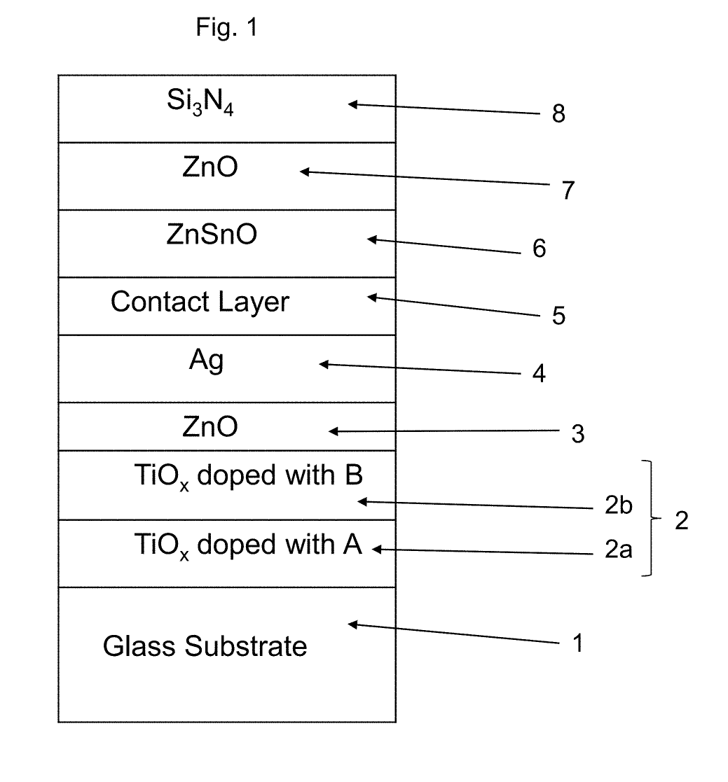

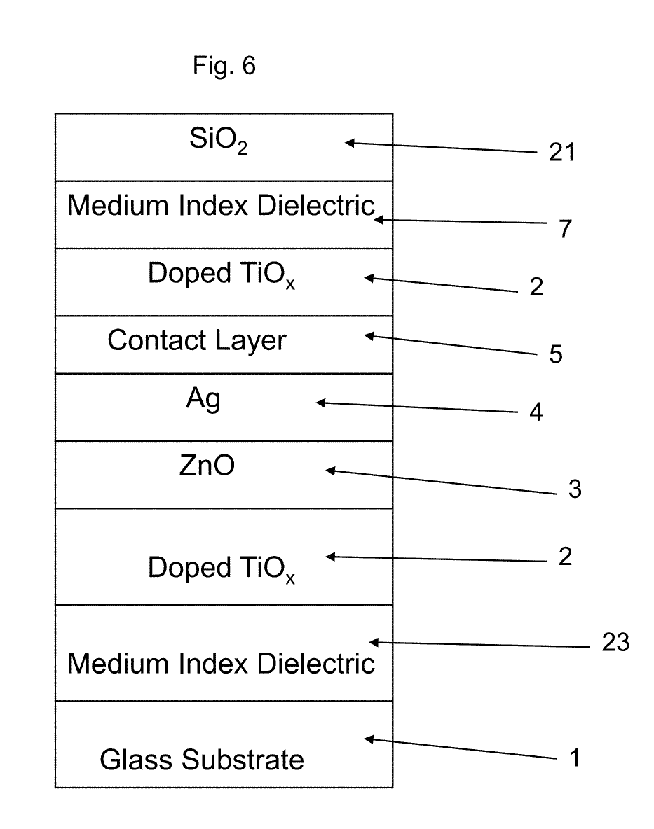

In certain example embodiments of this invention, a coated article includes a low emissivity (low-E) coating having at least one infrared (IR) reflecting layer 4 of a material such as silver, gold, or the like, and at least one high refractive index bi-layer film 2 of or including doped titanium oxide (e.g., TiO₂ doped with additional elements). See FIGS. 1 and 6 for example low-E coatings including such a high index film 2. The titanium oxide based bi-layer film 2 includes two or more layers and may be of or include a first titanium oxide based layer 2a doped with at least a first element, and an adjacent second titanium oxide based layer 2b doped with at least a different second element. Examples dopants for layers 2a and/or 2b include Sn, Zr, Y, Ba, Nb, and ZnSn. For example and without limitation, in film 2 high index transparent dielectric layer 2a may titanium oxide doped with at least Zr and high index transparent dielectric layer 2b may be titanium oxide doped with at least Sn. As another example, in film 2 high index transparent dielectric layer 2a may titanium oxide doped with at least Sn and high index transparent dielectric layer 2b may be titanium oxide doped with at least Zr. As another example, in film 2 high index transparent dielectric layer 2a may titanium oxide doped with at least ZnSn and high index transparent dielectric layer 2b may be titanium oxide doped with at least Zr. As another example, in film 2 high index transparent dielectric layer 2a may titanium oxide doped with at least Sn and high index transparent dielectric layer 2b may be titanium oxide doped with at least Y. As another example, in film 2 high index transparent dielectric layer 2a may titanium oxide doped with at least Sn and high index transparent dielectric layer 2b may be titanium oxide doped with at least Ba or Nb. As another example, in film 2 high index transparent dielectric layer 2a may titanium oxide doped with at least Y and high index transparent dielectric layer 2b may be titanium oxide doped with at least Sn, Ba, Nb or Zr. As another example, in film 2 high index transparent dielectric layer 2a may titanium oxide doped with at least Sn and high index transparent dielectric layer 2b may be titanium oxide doped with at least Y, Nb, Ba, or Zr. As another example, in film 2 high index transparent dielectric layer 2a may titanium oxide doped with at least Y, Ba, Nb, or Zr, and high index transparent dielectric layer 2b may be titanium oxide doped with at least Sn. In certain example embodiments, Ti has the highest metal content of any metal in layers 2a and 2b, and the dopant metal having the highest dopant metal content in layer 2a is a different element than the dopant metal having the highest dopant metal content in layer 2b (atomic %). For example, in film 2 high index transparent dielectric layer 2a may titanium oxide doped with at least Sn and high index transparent dielectric layer 2b may be titanium oxide doped with at least Zr and Sn, where there is more Zr than Sn in layer 2b in terms of atomic %. The high index bi-layer film 2 may be a transparent dielectric high index layer in preferred embodiments, which may be provided for antireflection purposes and/or color adjustment purposes, in addition to having thermal stability.

Thus, a crystalline high index TiO₂ layer for a low-E coating is split up into at least two thinner high index titanium oxide based layers 2a, 2b of different materials which in total may, for example, have a similar thickness to the convention TiO₂ layer. The doping of the two high index titanium oxide based layers 2a, 2b of film 2, with different materials, has several technical advantages. The degree to which the individual layers 2a and 2b can be crystallized during HT (e.g., thermal tempering) is reduced, as the amount of material used for each layer is less. Layers of different thicknesses have a different amount of thermal stress upon HT. The Young's modulus of the individual layers 2a and 2b varies with layer thickness, which reduces thermal stress of the film 2 and the surrounding layers, and hence improves heat treatability of the low-E coating. Moreover, one or both of layers 2a and/or 2b may be designed and deposited in a manner so as to be amorphous or substantially amorphous (as opposed to crystalline) in the low-E coating, so as to better withstand optional heat treatment (HT) such as thermal tempering. For example, it has been found that sputter-depositing the doped titanium oxide layers 2a and 2b of film 2 in an oxygen depleted atmosphere results in the doped titanium oxide layers 2a and 2b being deposited in an amorphous or substantially amorphous (as opposed to crystalline) state, which in turn surprisingly and unexpectedly allows the layer and overall coating to be more stable upon HT. It has been found that the difference in atomic radii between Ti and its dopant(s) (e.g., between Ti and Sn, or Ti and Ba, or Ti and Y, etc.) can be enhanced and adjusted by changing the oxidation states of both atoms by reducing oxygen content in the sputtering gas atmosphere used when sputter-depositing the layer, and this oxygen depletion in the sputtering atmosphere causes a lattice disorder (e.g., disruption in the lattice formation) and impedes the formation of crystals in the deposited doped titanium oxide layer, thereby leading to amorphous or substantially amorphous structure for sputter deposited layer(s) 2a and/or 2b which is stable even at high temperature thermal tempering. A large difference in ionic radii of Ti and dopant ions can disrupt the lattice and impede crystalline growth of the compound. The ionic radii depend on oxidation state and coordination number. Low oxygen conditions in the sputtering gaseous atmosphere force Ti into a lower oxidation state and/or lower coordination which in turn results in a larger difference in ionic radii with the dopant (e.g., Sn, SnZn, Ba, or Y). The oxygen depletion may also or instead cause Ti to move to the 4 coordination, which will also result in a large difference in ionic radii between Ti and Sn for instance. As a result, the doped titanium oxide layers 2a and/or 2b when sputter-deposited in an oxygen depleted atmosphere may be deposited in an amorphous or substantially amorphous state due to the large difference in ionic radii and lattice disruption and thus have thermal stability upon optional HT such as thermal tempering or heat bending. It will be appreciated that one or both of doped titanium oxide layers 2a and/or 2b of film 2 may be substoichiometric in certain example embodiments of this invention, so as to be only partially oxided, due to the oxygen depletion that may be used when depositing the layers.

“Substantially amorphous” as used herein means majority amorphous, and more amorphous than crystalline. For instance, “substantially amorphous” includes at least 60% amorphous, at least 80% amorphous, at least 90% amorphous, and fully amorphous. The amorphous or substantially amorphous high index doped titanium oxide layer(s) 2a and/or 2b may be a transparent dielectric high index layer, and may be oxided and/or nitrided, in preferred embodiments, and is provided for antireflection purposes and/or color adjustment purposes, in addition to having thermal stability. When the doped titanium oxide layer(s) 2a and/or 2b is/are nitrided, it is preferably that the nitrogen content be small such as from 0-10%, more preferably from 0-5% (atomic %).

Thus, one or both of doped titanium oxide layers 2a and/or 2b, of film 2, discussed herein may be sputter-deposited in an oxygen depleted atmosphere in order to realize and amorphous or substantially amorphous sputter deposited layer. In certain example embodiments of this invention, no more than 50% of the gaseous atmosphere in which the doped titanium oxide layer(s) 2a and/or 2b is sputter deposited is made up of oxygen gas, more preferably no more than 40%, even more preferably no more than 35%, and most preferably no more than 25%. The remainder of the gas in the atmosphere may be an inert gas such as argon gas, or the like. For example, an example 20% oxygen atmosphere in the sputtering chamber(s) is made up of 20% oxygen gas and 80% argon gas. Small amounts of other gas may also be included, intentionally or unintentionally.

FIG. 1 is a cross sectional view of a coated article according to an example embodiment of this invention. The coated article includes glass substrate 1 (e.g., clear, green, bronze, or blue-green glass substrate from about 1.0 to 10.0 mm thick, more preferably from about 1.0 mm to 6.0 mm thick), and a multi-layer coating (or layer system) provided on the substrate 1 either directly or indirectly. As shown in FIG. 1, the example low-E coating may be of or include high index amorphous or substantially amorphous transparent dielectric titanium oxide based film 2, including titanium oxide based layer 2a doped with at least a first dopant and titanium oxide based layer 2b doped with at least a different second dopant as discussed herein, zinc oxide and/or zinc stannate inclusive contact layer 3 (e.g., ZnOₓ where “x” may be about 1; or ZnAlOₓ), IR (infrared) reflecting layer 4 including or of silver, gold, or the like, upper contact layer 5 of or including an oxide of Ni and/or Cr (e.g., NiCrOₓ) or other suitable material, and a dielectric overcoat of or including dielectric layer 6 that may be a medium index layer such as zinc oxide or zinc stannate, or may be a high index titanium oxide doped film 2 discussed herein, optional medium index layer 7 of or including zinc oxide, tin oxide, and/or zinc stannate or other suitable material, and dielectric layer 8 of or including silicon nitride and/or silicon oxynitride or other suitable material. Silicon nitride inclusive layers (e.g., layer 8) may further include Al, oxygen, or the like, and the zinc oxide based layers may also include tin and/or aluminum. Other layers and/or materials may also be provided in the coating in certain example embodiments of this invention, and it is also possible that certain layers may be removed or split in certain example instances. For example, a zirconium oxide layer or an AlSiBOₓ layer (not shown) could be provided directly over and contacting silicon nitride layer 8. As another example, a medium index layer such as silicon nitride could be provided between the glass substrate 1 and high index film 2. As another example, two silver based IR reflecting layers, spaced apart by a dielectric layer stack including tin oxide for instance, may be provided and the overcoat and/or undercoat of FIG. 1 may be used therein. Moreover, one or more of the layers discussed above may be doped with other materials in certain example embodiments of this invention. This invention is not limited to the layer stack shown in FIG. 1, as the FIG. 1 stack is provided for purposes of example only in order to illustrate an example location(s) for a high index doped titanium oxide bi-layer film 2 discussed herein.

“Film” as used herein means one or more layers. Thus, in the FIG. 1 embodiment for example, there is a dielectric film above the IR reflecting layer 4 made up of one or more of layer(s) 6, 7 and/or 8; and a dielectric film below the IR reflecting layer made up of one or more of layers 2a, 2b and/or 3. Similarly, in the FIG. 6 embodiment for example, there is a dielectric film above the IR reflecting layer 4 made up of one or more of 2, 7 and/or 21; and a dielectric film below the IR reflecting layer made up of one or more of 23, 2 and/or 3.

In monolithic instances, the coated article includes only one substrate such as glass substrate 1 (see FIG. 1). However, monolithic coated articles herein may be used in devices such as IG window units for example. Typically, an IG window unit may include two or more spaced apart substrates with an air gap defined therebetween. Example IG window units are illustrated and described, for example, in U.S. Pat. Nos. 5,770,321, 5,800,933, 6,524,714, 6,541,084 and US 2003/0150711, the disclosures of which are all hereby incorporated herein by reference. For example, the coated glass substrate shown in FIG. 1 may be coupled to another glass substrate via spacer(s), sealant(s) or the like with a gap being defined therebetween in an IG window unit. In certain example instances, the coating may be provided on the side of the glass substrate 1 facing the gap, i.e., surface #2 or surface #3. In other example embodiments, the IG window unit may include additional glass sheets (e.g., the IG unit may include three spaced apart glass sheets instead of two).

Layers 2a and/or 2b of film 2 preferably each have a refractive index (n, measured at 550 nm) of at least 2.12, more preferably of at least 2.20, more preferably of at least 2.25. These layers may optionally include a small amount of nitrogen such as no greater than 15%, more preferably no greater than 10%, and most preferably no greater than 5% nitrogen (atomic %).

Layers 2a and/or 2b of film 2 are based on titanium oxide and preferably include titanium oxide (e.g., TiO₂ or TiOₓ where x is from 1.5 to 2.0, possibly from 1.6 to 1.99) doped with one or more of Nb, Sn, ZnSn, Y, Zr, and/or Ba as discussed herein. In certain example embodiments of this invention, doped titanium oxide layers 2a and 2b may each have a metal content of from about 70-99.5% Ti, more preferably from about 80-99% Ti, still more preferably from about 87-99% Ti, and from about 0.5 to 30% dopant, more preferably from about 1-20% dopant, and most preferably from about 1-13% dopant (atomic %), where the dopant is of or includes one or more of Sn, ZnSn, Y, Zr, Nb, and/or Ba. Higher dopant contents are possible in alternative embodiments of this invention. It has been found that these dopant amounts suffice for providing sufficient lattice mismatch upon oxygen depletion discussed herein, and also are low enough to allow the film 2 to have sufficiently high refractive index (n).

Transparent dielectric lower contact layer 3 may be of or include zinc oxide (e.g., ZnO), zinc stannate, or other suitable material. The zinc oxide of layer 3 may contain other materials as well such as Al (e.g., to form ZnAlOₓ) or Sn in certain example embodiments. For example, in certain example embodiments of this invention, zinc oxide layer 3 may be doped with from about 1 to 10% Al (or B), more preferably from about 1 to 5% Al (or B), and most preferably about 2 to 4% Al (or B). The use of zinc oxide 3 under the silver in layer 4 allows for an excellent quality of silver to be achieved. Zinc oxide layer 3 is typically deposited in a crystalline state. In certain example embodiments (e.g., to be discussed below) the zinc oxide inclusive layer 3 may be formed via sputtering a ceramic ZnO or metal rotatable magnetron sputtering target.

Infrared (IR) reflecting layer 4 is preferably substantially or entirely metallic and/or conductive, and may comprise or consist essentially of silver (Ag), gold, or any other suitable IR reflecting material. The silver of IR reflecting layer 4 may be doped with other material(s), such as with Pd, Zn, or Cu, in certain example embodiments. IR reflecting layer 4 helps allow the coating to have low-E and/or good solar control characteristics such as low emittance, low sheet resistance, and so forth. The IR reflecting layer may, however, be slightly oxidized in certain embodiments of this invention. Multiple silver based IR reflecting layers 4 may be provided, spaced apart in low-E coating by at least one dielectric layer, in double or triple silver stacks including doped titanium oxide layers discussed herein in certain example embodiments of this invention.

Upper contact layer 5 is located over and directly contacting the IR reflecting layer 4, and may be of or include an oxide of Ni and/or Cr in certain example embodiments. In certain example embodiments, upper contact layer 5 may be of or include nickel (Ni) oxide, chromium/chrome (Cr) oxide, or a nickel alloy oxide such as nickel chrome oxide (NiCrOₓ), or other suitable material(s) such as NiCrMoOₓ, NiCrMo, Ti, NiTiNbOₓ, TiOₓ, metallic NiCr, or the like. Contact layer 5 may or may not be oxidation graded in different embodiments of this invention. Oxidation grading means that the degree of oxidation in the layer changes through the thickness of the layer so that for example a contact layer may be graded so as to be less oxidized at the contact interface with the immediately adjacent IR reflecting layer 4 than at a portion of the contact layer further or more/most distant from the immediately adjacent IR reflecting layer. Contact layer 5 may or may not be continuous in different embodiments of this invention across the entire IR reflecting layer 4.

Other layer(s) below or above the illustrated FIG. 1 coating may also be provided. Thus, while the layer system or coating is “on” or “supported by” substrate 1 (directly or indirectly), other layer(s) may be provided therebetween. Thus, for example, the coating of FIG. 1 may be considered “on” and “supported by” the substrate 1 even if other layer(s) are provided between film 2 and substrate 1. Moreover, certain layers of the illustrated coating may be removed in certain embodiments, while others may be added between the various layers or the various layer(s) may be split with other layer(s) added between the split sections in other embodiments of this invention without departing from the overall spirit of certain embodiments of this invention.

While various thicknesses may be used in different embodiments of this invention, example thicknesses and materials for the respective layers on the glass substrate 1 in the FIG. 1 embodiment may be as follows, from the glass substrate outwardly (e.g., the Al content in the zinc oxide layer and the silicon nitride layers may be from about 1-10%, more preferably from about 1-5% in certain example instances). Thickness are in units of angstroms (Å), and are physical thicknesses.

TABLE 1
(Example Materials/Thicknesses; FIG. 1 Embodiment)

| | Preferred | More | |
|---|---|---|---|
| | Range | Preferred | Example |
| Layer | (Å) | (Å) | (Å) |
| Doped TiOₓ (bi-layer film 2) | 40-500 Å | 150-350 Å | 270 Å |
| ZnO or ZnAlOₓ (layer 3) | 10-240 Å | 35-120 Å | 40 Å |
| Ag (layer 4) | 40-160 Å | 65-125 Å | 110 Å |
| Contact (layer 5) | 10-70 Å | 20-50 Å | 34 Å |
| ZnSnO/doped TiOₓ (layer 6) | 30-350 Å | 80-200 Å | 100 Å |
| ZnO or ZnAlOₓ (layer 7) | 10-240 Å | 35-120 Å | 40 Å |
| SiₓN_{y} (layer 8) | 50-250 Å | 80-180 Å | 100 Å |

In certain example embodiments, in bi-layer film 2 doped titanium oxide layer 2a may be from about 20-400 Åthick more preferably from about 50-240 Åthick, and most preferably from about 70-170 Åthick. And in certain example embodiments, doped titanium oxide layer 2b may also be from about 20-400 Åthick more preferably from about 50-240 Åthick, and most preferably from about 70-170 Åthick. In certain example embodiments, layer 2b may be thicker than layer 2a by at least 20 Å, more preferably by at least 40 Å.

In certain example embodiments of this invention, coated articles herein (e.g., see FIG. 1) may have the following low-E (low emissivity), solar and/or optical characteristics set forth in Table 2 when measured monolithically.

TABLE 2
Low-E/Solar Characteristics (Monolithic)

| Characteristic | General | More Preferred | Most Preferred |
|---|---|---|---|
| Rₛ (ohms/sq.): | <=11.0 | <=10 | <=9 |
| Eₙ: | <=0.2 | <=0.15 | <=0.10 |
| Tᵥᵢₛ (%): | >=50 | >=60 | >=70 |

While high index transparent dielectric doped titanium oxide bi-layer film 2 is shown and described in connection with the low-E coating of FIG. 1 above, this invention is not so limited. Doped titanium oxide high index transparent dielectric bi-layer films 2 described herein may be used as a high index films/layer(s) in any suitable low-E coating either above or below an IR reflecting layer(s). One or more of such doped titanium oxide bi-layer films 2 may be provided in any suitable low-E coating. For example and without limitation, amorphous or substantially amorphous doped titanium oxide bi-layer film 2 as described above and/or herein may be used to replace any high index (e.g., TiOₓ or TiO₂) layer in any of the low-E coatings in any of U.S. Pat. Nos. 9,212,417, 9,297,197, 7,390,572, 7,153,579, 9,365,450, and 9,403,345, all of which are incorporated herein by reference.

FIG. 6 is a cross sectional view of a coated article according to another example embodiment of this invention. FIG. 6 is similar to FIG. 1, except that in the FIG. 6 embodiment a medium index (n) layer 23 of or including material such as silicon nitride or zinc oxide is provided between and directly contacting the glass substrate 1 and the doped titanium oxide bi-layer film 2, and a low index layer 21 of a material such as SiO₂ is provided in place of layer 8. It is noted that doped titanium oxide film 2 as discussed herein is used for the layer immediately above contact layer 5 in the FIG. 6 embodiment.

Examples according to certain example embodiments of this invention are as follows.

A Comparative Example (CE) is described above in connection with FIG. 2, utilizing an undoped TiO₂ layer in the position of film 2.

### Example 1

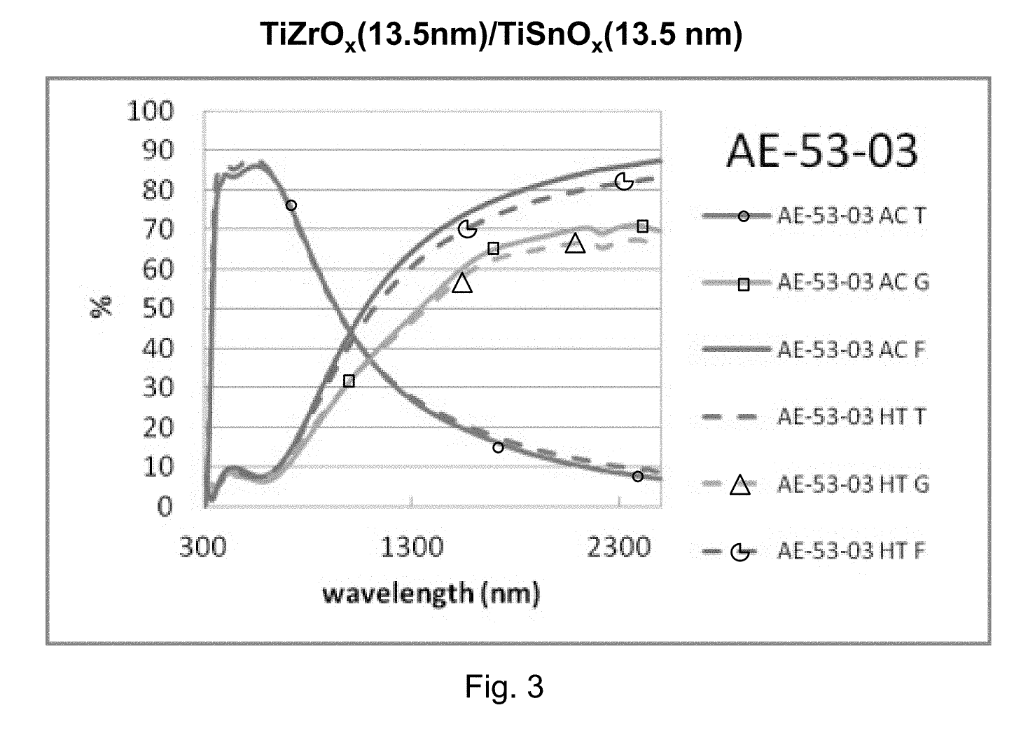

Example 1 was a low-E coating on a glass substrate according to the FIG. 1 embodiment, for comparing to FIG. 2 above. The Example 1 layer stack was glass/TiZrOₓ (13.5 nm)/TiSnOₓ (13.5 nm)/ZnO (4 nm)/Ag (11 nm)/NiTiNbOₓ (2.4 nm)/ZnSnO (10 nm)/ZnO (4 nm)/SiN (10 nm), where the ZnO layers were doped with Al. Example 1 was the same coating stack as the Comparative Example (CE) described above regarding FIG. 2, except that in Example 1 the undoped TiO₂ layer of the CE was replaced with bilayer film 2 of Zr-doped titanium oxide (TiZrOₓ) layer 2a and Sn-doped titanium oxide (TiSnOₓ) layer 2b. Metal content of the TiSnOₓ layer 2b was 88% Ti and 12% Sn (atomic %). The TiSnOₓ layer 2b of Example 1 had a refractive index (n), at 550 nm, of 2.27. FIG. 3 shows the data of Example 1, before and after HT, and should be compared to the CE of FIG. 2. In FIGS. 2 and 3 at the right side where the curves are listed, the top three are “as coated” (AC) which means prior to the HT, and the bottom three are following the heat treatment and thus are labeled “HT.” Thus, the AC curves are prior to HT, and the HT curves are after heat treatment at about 650 degrees C. for about eight minutes. The layers 2a and 2b were amorphous or substantially amorphous both as deposited and following the HT.

Comparing FIG. 3 of Example 1 to the Comparative Example (CE) in FIG. 2, significant unexpected differences are demonstrated resulting from the different dopings of titanium oxide based layers 2a and 2b. In FIG. 2, for the CE in the wavelength area from about 1500 to 2400 nm, there was a shift due to HT from the “AC T” (transmission, as coated prior to HT) curve to the “HT T” (transmission, after HT) curve of about 6%; there was a shift due to HT from the “AC G” (glass side reflectance, as coated prior to HT) curve to the “HT G” (glass side reflectance, after HT) curve of about 12-14%; and there was a shift due to HT from the “AC F” (film side reflectance, as coated prior to HT) curve to the “HT F” (film side reflectance, after HT) curve of about 12-13%. Overall, taken together in combination, there is a significant shift in transmission and reflection spectra upon HT which indicates a lack of thermal stability for the CE in FIG. 2. The Comparative Example (CE) of FIG. 2 shows a significant shift in the IR range of the transmission and reflectance spectra, and increases in emissivity and haze were also found. In contrast, upon doping the titanium oxide layers 2a and 2b in Example 1, FIG. 3 shows that in the wavelength area from about 1500 to 2400 nm there was very little shift due to HT from the “AC T” (transmission, as coated prior to HT) curve to the “HT T” (transmission, after HT) curve of less than 4%; there was little shift due to HT from the “AC G” (glass side reflectance, as coated prior to HT) curve to the “HT G” (glass side reflectance, after HT) curve of less than 5-6%; and there was very little shift due to HT from the “AC F” (film side reflectance, as coated prior to HT) curve to the “HT F” (film side reflectance, after HT) curve of less than 6 or 7%. These much smaller shifts due to HT result from the layers 2a and 2b being in amorphous or substantially amorphous form due to the dopants in layers 2a and 2b in Example 1, and demonstrate thermal stability and heat treatability of the Example 1 coating. For example, the reflection of the coated article of Example 1 at 2250 nm changed by −4.25% due to the HT, whereas the reflection of the CE of FIG. 2 at 2250 nm changed by a much higher −8.84%, demonstrating that Example 1 was much improved with respect to thermal stability upon HT compared to the CE. Moreover, the normal emissivity (En) of Example 1 changed by only 0.026 due to the HT, whereas En of the CE in FIG. 2 changed by a much higher amount of 0.065 due to the HT, demonstrating that Example 1 was much improved with respect to thermal stability upon HT compared to the CE. Accordingly, comparing FIG. 3 to FIG. 2, it can be seen that Example 1 was surprisingly and unexpectedly improved compared to the CE with respect to thermal stability and heat treatability (e.g., thermal tempering).

### Example 2

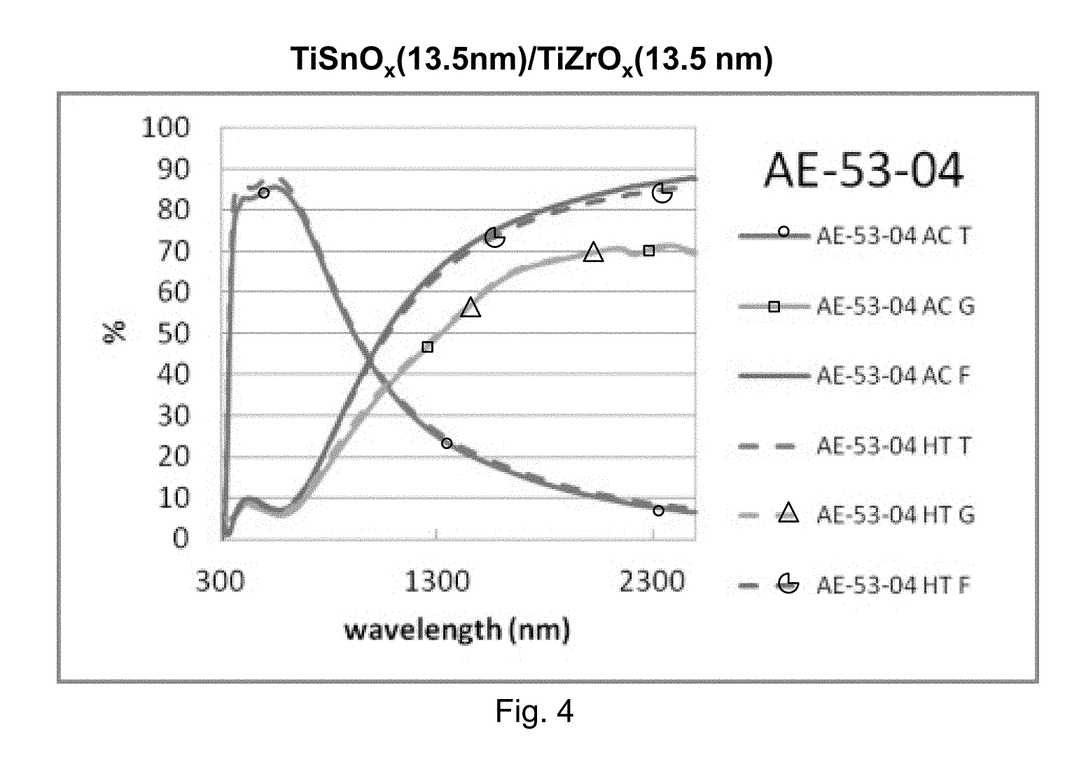

Example 2 (FIG. 4) was the same as Example 1, except that the ordering of layers 2a and 2b in Example 1 was reversed. The Example 2 layer stack was glass/TiSnOₓ (13.5 nm)/TiZrOₓ (13.5 nm)/ZnO (4 nm)/Ag (11 nm)/NiTiNbOₓ (2.4 nm)/ZnSnO (10 nm)/ZnO (4 nm)/SiN (10 nm), where the ZnO layers were doped with Al. Thus, Example 2 was the same coating stack as the Comparative Example (CE) described above regarding FIG. 2, except that in Example 2 the undoped TiO₂ layer of the CE was replaced with bilayer film 2 of Zr-doped titanium oxide (TiZrOₓ) layer 2b and Sn-doped titanium oxide (TiSnOₓ) layer 2a. FIG. 4 shows the data of Example 2, before and after HT, and should be compared to the CE of FIG. 2. In FIGS. 2 and 4 at the right side where the curves are listed, the top three are “as coated” (AC) which means prior to the HT, and the bottom three are following the heat treatment and thus are labeled “HT.” Thus, the AC curves are prior to HT, and the HT curves are after heat treatment at about 650 degrees C. for about eight minutes. The layers 2a and 2b were amorphous or substantially amorphous both as deposited and following the HT.

Comparing FIG. 4 of Example 2 to the Comparative Example (CE) in FIG. 2, significant unexpected differences are demonstrated resulting from the different dopings of titanium oxide based layers 2a and 2b. In FIG. 2, for the CE in the wavelength area from about 1500 to 2400 nm, there was a shift due to HT from the “AC T” (transmission, as coated prior to HT) curve to the “HT T” (transmission, after HT) curve of about 6%; there was a shift due to HT from the “AC G” (glass side reflectance, as coated prior to HT) curve to the “HT G” (glass side reflectance, after HT) curve of about 12-14%; and there was a shift due to HT from the “AC F” (film side reflectance, as coated prior to HT) curve to the “HT F” (film side reflectance, after HT) curve of about 12-13%. Overall, taken together in combination, there is a significant shift in transmission and reflection spectra upon HT which indicates a lack of thermal stability for the CE in FIG. 2. The Comparative Example (CE) of FIG. 2 shows a significant shift in the IR range of the transmission and reflectance spectra, and increases in emissivity and haze were also found. In contrast, upon doping the titanium oxide layers 2a and 2b in Example 2, FIG. 4 shows that in the wavelength area from about 1500 to 2400 nm there was very little shift due to HT from the “AC T” (transmission, as coated prior to HT) curve to the “HT T” (transmission, after HT) curve of less than 2 or 3%; there was little shift due to HT from the “AC G” (glass side reflectance, as coated prior to HT) curve to the “HT G” (glass side reflectance, after HT) curve of less than 3-4%; and there was very little shift due to HT from the “AC F” (film side reflectance, as coated prior to HT) curve to the “HT F” (film side reflectance, after HT) curve of less than 3-4%. These much smaller shifts due to HT result from the layers 2a and 2b being in amorphous or substantially amorphous form due to the dopants in layers 2a and 2b in Example 2, and demonstrate thermal stability and heat treatability of the Example 2 coating. For example, the reflection of the coated article of Example 2 at 2250 nm changed by −1.78% due to the HT, whereas the reflection of the CE of FIG. 2 at 2250 nm changed by a much higher −8.84%, demonstrating that Example 2 was much improved with respect to thermal stability upon HT compared to the CE. Moreover, the normal emissivity (En) of Example 2 changed by only 0.002 due to the HT, whereas En of the CE in FIG. 2 changed by a much higher amount of 0.065 due to the HT, again demonstrating that Example 2 was much improved with respect to thermal stability upon HT compared to the CE. Accordingly, comparing FIG. 4 to FIG. 2, it can be seen that Example 2 was surprisingly and unexpectedly improved compared to the CE with respect to thermal stability and heat treatability (e.g., thermal tempering).

### Example 3

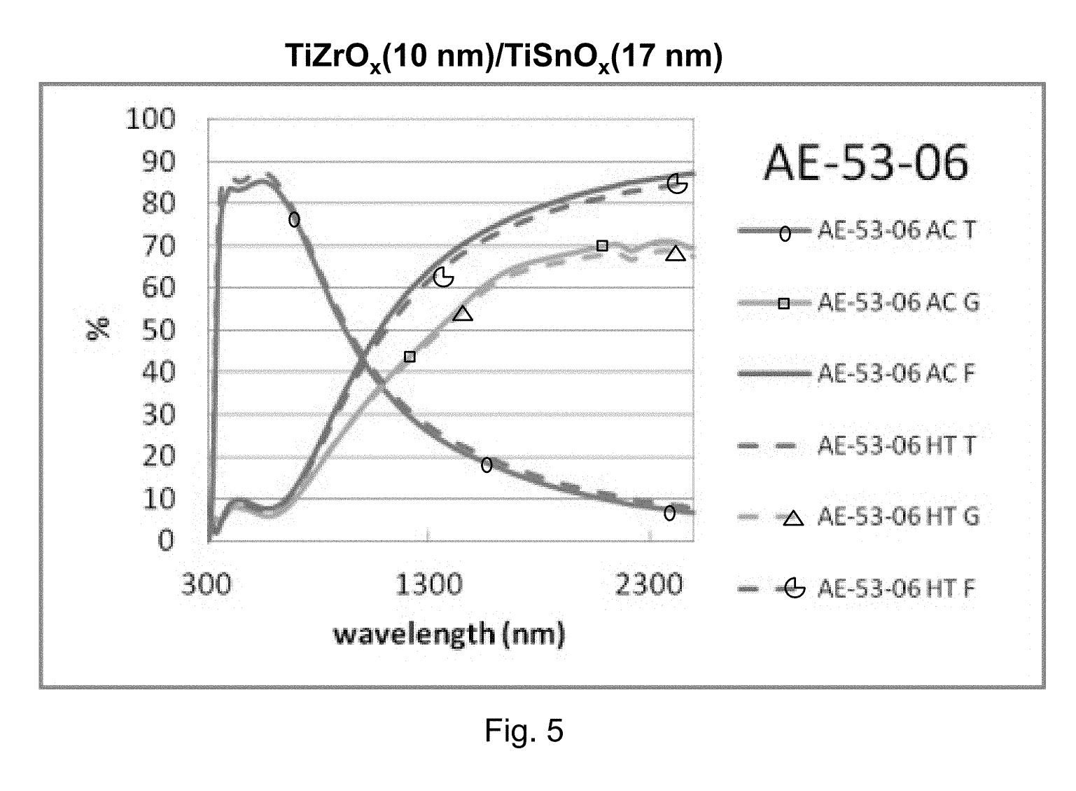

Example 3 (FIG. 5) was the same layer stack as Example 1, except for the different thicknesses of layers 2a and 2b. The layer stack in Example 3 was glass/TiZrOₓ (10 nm)/TiSnOₓ (17 nm)/ZnO (4 nm)/Ag (11 nm)/NiTiNbOₓ (2.4 nm)/ZnSnO (10 nm)/ZnO (4 nm)/SiN (10 nm), where the ZnO layers were doped with Al. Thus, Example 3 was the same coating stack as the Comparative Example (CE) described above regarding FIG. 2, except that in Example 3 the undoped TiO₂ layer of the CE was replaced with bilayer film 2 of Zr-doped titanium oxide (TiZrOₓ) layer 2a and Sn-doped titanium oxide (TiSnOₓ) layer 2b. FIG. 5 shows the data of Example 3, before and after HT, and should be compared to the CE of FIG. 2. In FIGS. 2 and 5 at the right side where the curves are listed, the top three are “as coated” (AC) which means prior to the HT, and the bottom three are following the heat treatment and thus are labeled “HT.” Thus, the AC curves are prior to HT, and the HT curves are after heat treatment at about 650 degrees C. for about eight minutes. The layers 2a and 2b were amorphous or substantially amorphous both as deposited and following the HT.

Comparing FIG. 5 of Example 2 to the Comparative Example (CE) in FIG. 2, significant unexpected differences are demonstrated resulting from the different dopings of titanium oxide based layers 2a and 2b. In FIG. 2, for the CE in the wavelength area from about 1500 to 2400 nm, there was a shift due to HT from the “AC T” (transmission, as coated prior to HT) curve to the “HT T” (transmission, after HT) curve of about 6%; there was a shift due to HT from the “AC G” (glass side reflectance, as coated prior to HT) curve to the “HT G” (glass side reflectance, after HT) curve of about 12-14%; and there was a shift due to HT from the “AC F” (film side reflectance, as coated prior to HT) curve to the “HT F” (film side reflectance, after HT) curve of about 12-13%. Overall, taken together in combination, there is a significant shift in transmission and reflection spectra upon HT which indicates a lack of thermal stability for the CE in FIG. 2. The Comparative Example (CE) of FIG. 2 shows a significant shift in the IR range of the transmission and reflectance spectra, and increases in emissivity and haze were also found. In contrast, upon doping the titanium oxide layers 2a and 2b in Example 3, FIG. 5 shows that in the wavelength area from about 1500 to 2400 nm there was very little shift due to HT from the “AC T” (transmission, as coated prior to HT) curve to the “HT T” (transmission, after HT) curve of less than 2 or 3%; there was little shift due to HT from the “AC G” (glass side reflectance, as coated prior to HT) curve to the “HT G” (glass side reflectance, after HT) curve of less than 3-4%; and there was very little shift due to HT from the “AC F” (film side reflectance, as coated prior to HT) curve to the “HT F” (film side reflectance, after HT) curve of less than 3-4%. These much smaller shifts due to HT result from the layers 2a and 2b being in amorphous or substantially amorphous form due to the dopants in layers 2a and 2b in Example 3, and demonstrate thermal stability and heat treatability of the Example 3 coating. For example, the reflection of the coated article of Example 3 at 2250 nm changed by −2.07% due to the HT, whereas the reflection of the CE of FIG. 2 at 2250 nm changed by a much higher −8.84%, demonstrating that Example 3 was much improved with respect to thermal stability upon HT compared to the CE. Moreover, the normal emissivity (En) of Example 3 changed by only 0.006 due to the HT, whereas En of the CE in FIG. 2 changed by a much higher amount of 0.065 due to the HT, demonstrating that Example 3 was much improved with respect to thermal stability upon HT compared to the CE. Accordingly, comparing FIG. 5 to FIG. 2, it can be seen that Example 3 was surprisingly and unexpectedly improved compared to the CE with respect to thermal stability and heat treatability (e.g., thermal tempering).

In an example embodiment of this invention, there is provided a coated article including a coating supported by a glass substrate, the coating comprising: a first transparent dielectric film on the glass substrate; an infrared (IR) reflecting layer comprising silver on the glass substrate, located over at least the first transparent dielectric film; a second transparent dielectric film on the glass substrate, located over at least the IR reflecting layer; and wherein at least one of the first and second transparent dielectric films comprises a first layer comprising an oxide of titanium doped with a first metal element M1, and a second layer comprising an oxide of titanium doped with a second metal element M2 that is located over and directly contacting the first layer comprising the oxide of titanium doped with the first element M1, and wherein the first and second elements M1 and M2 are different.

In the coated article of the immediately preceding paragraph, at least one of said first layer comprising the oxide of titanium doped with the first element M1 and said second layer comprising the oxide of titanium doped with the second element M2 may be amorphous or substantially amorphous.

In the coated article of any of the preceding two paragraphs, Ti may have the highest metal content of any metal in each of said first layer comprising the oxide of titanium doped with the first element M1 and said second layer comprising the oxide of titanium doped with the second element M2, and wherein M1 may have the highest metal content of any metal in said first layer comprising the oxide of titanium doped with the first element M1 other than Ti, and M2 may have the highest metal content of any metal in said second layer comprising the oxide of titanium doped with the second element M2 other than Ti (atomic %).

In the coated article of any of the preceding three paragraphs, M1 and M2 are different but may each be selected from the group consisting of Sn, SnZn, Zr, Y, Nb, and Ba.

In the coated article of any of the preceding four paragraphs, metal content of said first layer comprising the oxide of titanium doped with the first element M1 may comprise from about 70-99.5% (more preferably from about 80-99%, and most preferably from about 87-99%) Ti and from about 0.5-30% (more preferably from about 1-20%, and most preferably from about 1-13%) of M1 (atomic %).

In the coated article of any of the preceding five paragraphs, metal content of said second layer comprising the oxide of titanium doped with the second element M2 may comprise from about 70-99.5% (more preferably from about 80-99%, and most preferably from about 87-99%) Ti and from about 0.5-30% (more preferably from about 1-20%, and most preferably from about 1-13%) M2 (atomic %).

In the coated article of any of the preceding six paragraphs, said first layer comprising the oxide of titanium doped with the first element M1 may further comprise M2, but where metal content of M1 is greater than metal content of M2 in said first layer (atomic %).

In the coated article of any of the preceding seven paragraphs, said second layer comprising the oxide of titanium doped with the second element M2 may further comprise M1, but where metal content of M2 is greater than metal content of M1 in said second layer (atomic %).

In the coated article of any of the preceding eight paragraphs, at least one of said first layer comprising the oxide of titanium doped with the first element M1 and said second layer comprising the oxide of titanium doped with the second element M2 may further comprise a dopant M3, wherein M3 is different than M1 and M2 and may be selected from the group consisting of Sn, SnZn, Zr, Y, Nb, and Ba.

In the coated article of any of the preceding nine paragraphs, M1 may comprise Sn.

In the coated article of any of the preceding ten paragraphs, M1 may comprise Zr.

In the coated article of any of the preceding eleven paragraphs, M1 may comprise Y.

In the coated article of any of the preceding twelve paragraphs, M1 may comprise Nb.

In the coated article of any of the preceding thirteen paragraphs, M1 may comprise Ba.

In the coated article of any of the preceding fourteen paragraphs, M2 may comprise Sn.

In the coated article of any of the preceding fifteen paragraphs, M2 may comprises Zr.

In the coated article of any of the preceding sixteen paragraphs, M2 may comprise Y.

In the coated article of any of the preceding seventeen paragraphs, M2 may comprise Nb.

In the coated article of any of the preceding eighteen paragraphs, M2 may comprise Ba.

In the coated article of any of the preceding nineteen paragraphs, the first and/or second layer may have a refractive index (n) of at least 2.12, more preferably of at least 2.20, and most preferably of at least 2.25.

In the coated article of any of the preceding twenty paragraphs, the coating may be a low-E coating and have a normal emissivity (En) of no greater than 0.2, more preferably no greater than 0.10.

In the coated article of any of the preceding twenty one paragraphs, the first and/or second layer may comprise an oxide of titanium doped with SnZn.

In the coated article of any of the preceding twenty two paragraphs, the coating may further comprise a layer comprising zinc oxide located under and directly contacting the IR reflecting layer.

In the coated article of any of the preceding twenty three paragraphs, the coating may further comprise a layer comprising silicon nitride located on and directly contacting the glass substrate.

In the coated article of any of the preceding twenty four paragraphs, the coating may further comprise a layer comprising an oxide of Ni and/or Cr located over and directly contacting the IR reflecting layer.

In the coated article of any of the preceding twenty five paragraphs, the coated article may be thermally tempered.

In the coated article of any of the preceding twenty six paragraphs, the coated article may have a visible transmission of at least 50%, more preferably of at least 60%, and most preferably of at least 70%.

In the coated article of any of the preceding twenty seven paragraphs, said first transparent dielectric film may comprise the first layer comprising the oxide of titanium doped with the first metal element M1, and the second layer comprising the oxide of titanium doped with the second metal element M2.

In the coated article of any of the preceding twenty eight paragraphs, said second transparent dielectric film may comprise the first layer comprising the oxide of titanium doped with the first metal element M1, and the second layer comprising the oxide of titanium doped with the second metal element M2.

In the coated article of any of the preceding twenty nine paragraphs, the coating may further comprise a layer comprising silicon oxide located over the second transparent dielectric film.

The coated article of any of the preceding thirty paragraphs may be made using a method wherein sputter depositing of at least one of the first and second transparent dielectric films comprises sputter depositing the first layer comprising the oxide of titanium doped with the first metal element M1, and the second layer comprising the oxide of titanium doped with the second metal element M2, so that at least one of the first and second layers is sputter deposited so as to be amorphous or substantially amorphous. Sputter depositing of such an amorphous or substantially amorphous layer may be performed in an oxygen depleted gaseous atmosphere so that a difference in radii for metals during sputtering causes lattice disorder leading to amorphous or substantially amorphous structure of the layer. During sputter depositing the amorphous or substantially amorphous layer the sputter depositing may be controlled, via control oxygen gas in the sputtering atmosphere and/or oxygen in sputtering target material, so as to cause an average difference of at least 15 pm (more preferably at least 20 pm) in ionic radii between Ti and at least one of Sn, SnZn, Zr, Y, and Ba and thus a lattice disorder leading to amorphous or substantially amorphous structure of the layer being sputter deposited.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A coated article including a coating supported by a glass substrate, the coating comprising:
a first transparent dielectric film on the glass substrate;
an infrared (IR) reflecting layer comprising silver on the glass substrate, located over at least the first transparent dielectric film;
a second transparent dielectric film on the glass substrate, located over at least the IR reflecting layer; and
wherein at least one of the first and second transparent dielectric films comprises a first layer comprising an oxide of titanium doped with a first metal element M1, and a second layer comprising an oxide of titanium doped with a second metal element M2 that is located over and directly contacting the first layer comprising the oxide of titanium doped with the first element M1, and wherein the first and second elements M1 and M2 are different.

2. The coated article of claim 1, wherein at least one of said first layer comprising the oxide of titanium doped with the first element M1 and said second layer comprising the oxide of titanium doped with the second element M2 is amorphous or substantially amorphous.

3. The coated article of claim 1, wherein Ti has the highest metal content of any metal in each said of first layer comprising the oxide of titanium doped with the first element M1 and said second layer comprising the oxide of titanium doped with the second element M2, and wherein M1 has the highest metal content of any metal in said first layer comprising the oxide of titanium doped with the first element M1 other than Ti, and M2 has the highest metal content of any metal in said second layer comprising the oxide of titanium doped with the second element M2 other than Ti (atomic %).

4. The coated article of claim 1, wherein M1 and M2 are different but are each selected from the group consisting of Sn, SnZn, Zr, Y, Nb, and Ba.

5. The coated article of claim 1, wherein metal content of said first layer comprising the oxide of titanium doped with the first element M1 comprises from about 70-99.5% Ti and from about 0.5-30% of M1 (atomic %).

6. The coated article of claim 1, wherein metal content of said second layer comprising the oxide of titanium doped with the second element M2 comprises from about 70-99.5% Ti and from about 0.5-30% of M2 (atomic %).

7. The coated article of claim 1, wherein said first layer comprising the oxide of titanium doped with the first element M1 further comprises M2, but wherein metal content of M1 is greater than metal content of M2 in said first layer (atomic %).

8. The coated article of claim 1, wherein said second layer comprising the oxide of titanium doped with the second element M2 further comprises M1, but wherein metal content of M2 is greater than metal content of M1 in said second layer (atomic %).

9. The coated article of claim 1, wherein at least one of said first layer comprising the oxide of titanium doped with the first element M1 and said second layer comprising the oxide of titanium doped with the second element M2 further comprises a dopant M3, wherein M3 is different than M1 and M2 and is selected from the group consisting of Sn, SnZn, Zr, Y, Nb, and Ba.

10. The coated article of claim 1, wherein M1 comprises Sn.

11. The coated article of claim 1, wherein M1 comprises Zr.

12. The coated article of claim 1, wherein M1 comprises Y.

13. The coated article of claim 1, wherein M1 comprises Nb.

14. The coated article of claim 1, wherein M1 comprises Ba.

15. The coated article of claim 1, wherein M2 comprises Sn.

16. The coated article of claim 1, wherein M2 comprises Zr.

17. The coated article of claim 1, wherein M2 comprises Y.

18. The coated article of claim 1, wherein M2 comprises Nb.

19. The coated article of claim 1, wherein M2 comprises Ba.

20. The coated article of claim 1, wherein the first and/or second layer has a refractive index (n) of at least 2.12.

21. The coated article of claim 1, wherein the first and/or second layer has a refractive index (n) of at least 2.20.

22. The coated article of claim 1, wherein the coating is a low-E coating and has a normal emissivity (En) of no greater than 0.2.

23. The coated article of claim 1, wherein the coating is a low-E coating and has a normal emissivity (En) of no greater than 0.10.

24. The coated article of claim 1, wherein the first and/or second layer comprises an oxide of titanium doped with SnZn.

25. The coated article of claim 1, wherein the coating further comprises a layer comprising zinc oxide located under and directly contacting the IR reflecting layer.

26. The coated article of claim 1, wherein the coating further comprises a layer comprising silicon nitride located on and directly contacting the glass substrate.

27. The coated article of claim 1, wherein the coating further comprises a layer comprising an oxide of Ni and/or Cr located over and directly contacting the IR reflecting layer.

28. The coated article of claim 1, wherein the coated article is thermally tempered.

29. The coated article of claim 1, wherein the coated article has a visible transmission of at least 50%.

30. The coated article of claim 1, wherein said first transparent dielectric film comprises the first layer comprising the oxide of titanium doped with the first metal element M1, and the second layer comprising the oxide of titanium doped with the second metal element M2.

31. The coated article of claim 1, wherein said second transparent dielectric film comprises the first layer comprising the oxide of titanium doped with the first metal element M1, and the second layer comprising the oxide of titanium doped with the second metal element M2.

32. The coated article of claim 31, wherein the coating further comprises a layer comprising silicon oxide located over the second transparent dielectric film.

33. A method of making a coated article including a coating supported by a glass substrate, the method comprising:
sputter depositing a first transparent dielectric film on the glass substrate;
sputter depositing an infrared (IR) reflecting layer on the glass substrate, located over at least the first transparent dielectric film;
sputter depositing a second transparent dielectric film on the glass substrate, located over at least the IR reflecting layer; and
wherein said sputter depositing of at least one of the first and second transparent dielectric films comprises sputter depositing a first layer comprising an oxide of titanium doped with a first metal element M1, and a second layer comprising an oxide of titanium doped with a second metal element M2 that is located over and directly contacting the first layer comprising the oxide of titanium doped with the first element M1, and wherein the first and second elements M1 and M2 are different.

34. The method of claim 33, wherein at least one of the first and second layers is sputter deposited so as to be amorphous or substantially amorphous.

35. The method of claim 33, wherein at least one of the first and second layers is sputter-deposited, so as to be amorphous or substantially amorphous, in an oxygen depleted atmosphere so that a difference in radii for metals during sputtering causes lattice disorder leading to amorphous or substantially amorphous structure of the layer.

36. The method of claim 35, where during sputter depositing the amorphous or substantially amorphous layer the sputter depositing is controlled, via control oxygen gas in the sputtering atmosphere and/or oxygen in sputtering target material, so as to cause an average difference of at least 15 pm in ionic radii between Ti and at least one of Sn, SnZn, Zr, Y, and Ba and thus a lattice disorder leading to amorphous or substantially amorphous structure of the layer being sputter deposited.

37. The method of claim 33, wherein Ti has the highest metal content of any metal in each said of first layer comprising the oxide of titanium doped with the first element M1 and said second layer comprising the oxide of titanium doped with the second element M2, and wherein M1 has the highest metal content of any metal in said first layer comprising the oxide of titanium doped with the first element M1 other than Ti, and M2 has the highest metal content of any metal in said second layer comprising the oxide of titanium doped with the second element M2 other than Ti (atomic %).

38. The method of claim 33, wherein M1 and M2 are different but are each selected from the group consisting of Sn, SnZn, Zr, Y, Nb, and Ba.

39. The method of claim 33, wherein metal content of said first layer comprising the oxide of titanium doped with the first element M1 comprises from about 70-99.5% Ti and from about 0.5-30% of M1 (atomic %).

40. The method of claim 33, wherein metal content of said second layer comprising the oxide of titanium doped with the second element M2 comprises from about 70-99.5% Ti and from about 0.5-30% of M2 (atomic %).
